(19) United States
(12) Patent Application Publication
(10) Pub. No.: US 2018/0130970 A1
(43) Pub. Date: May 10, 2018

(54) DISPLAY PANEL, DISPLAY DEVICE AND METHOD OF MANUFACTURING DISPLAY PANEL

(71) Applicants: BOE TECHNOLOGY GROUP CO., LTD., Beijing (CN); Ordos Yuansheng Optoelectronics Co., Ltd., Ordos (CN)

(72) Inventors: Zifeng Wang, Beijing (CN); Lina Wang, Beijing (CN); Chunsheng Gu, Beijing (CN); Xuefei Bai, Beijing (CN); Dan Jia, Beijing (CN)

(21) Appl. No.: 15/705,128

(22) Filed: Sep. 14, 2017

(30) Foreign Application Priority Data
Nov. 7, 2016 (CN) 201610973592.4

(51) Int. Cl. H01L 51/52; H01L 27/32; H01L 51/56; H01L 51/00

(52) U.S. Cl. CPC H01L 51/525; H01L 27/3244; H01L 51/0034; H01L 51/56; H01L 27/3281

(57) ABSTRACT

The present disclosure provides a display panel, a display device and a method of manufacturing the display panel. The display panel includes: a first substrate; a second substrate arranged to face the first substrate; and at least one spacer arranged between the first substrate and the second substrate and spaced apart from each other. The at least one spacer includes: a first support portion provided on the first substrate, and a second support portion provided on the second substrate, the first support portion and the second support portion are fixedly connected with each other, and modulus of elasticity of a material of the first support portion is less than the modulus of elasticity of a material of the second support portion.

### CROSS-REFERENCE TO RELATED APPLICATION

This application claims the benefit of the Chinese Patent Application No. 201610973592.4 titled “Display Panel, Display Device and Method of Manufacturing Display Panel” and filed on Nov. 7, 2016 in the State Intellectual Property Office of China, the whole disclosure of which is incorporated herein by reference.

### BACKGROUND

### Technical Field

The present disclosure generally relates to the field of display technologies, and in particular, to a display panel, a display device comprising the display panel and a method of manufacturing the display panel.

### Description of Related Art

A spacer needs to be provided during production of a display panel; for example, in order to inject liquid crystal between an upper substrate and a lower substrate of a liquid crystal display panel, a spacer needs to be arranged to provide a gap between the upper substrate and the lower substrate; and in an organic light emitting diode display panel, the spacers need to be provided among pixels and between the pixel and a glass glue or sealant in order to prevent the pixel from being pressed and damaged.

### SUMMARY

The present disclosure provides a display panel, a display device and a method of manufacturing a display panel.

According to an aspect of the present disclosure, there is provided a display panel, comprising:

a first substrate;

a second substrate arranged to face the first substrate; and

at least one spacer arranged between the first substrate and the second substrate and spaced apart from each other, wherein the at least one spacer comprises:

a first support portion provided on the first substrate, and

a second support portion provided on the second substrate, the first support portion and the second support portion are fixedly connected with each other, and modulus of elasticity of a material of the first support portion is less than the modulus of elasticity of a material of the second support portion.

In one example, the first support portion and/or second support portion are/is made of an organic polymer material.

In one example, the organic polymer material includes polyimide composite resin.

In one example, a degree of polymerization of the polyimide composite resin of the first support portion is less than a degree of polymerization of the polyimide composite resin of the second support portion.

In one example, the first support portion and second support portion are fixedly connected with each other through an adhesive.

In one example, the first support portion and second support portion are connected with each other through an engagement structure including a protrusion and a recess.

In one example, one of a surface of the first support portion facing towards the second support portion and a surface of the second support portion facing towards the first support portion is formed with at least one protrusion, and the other one is formed with at least one recess, the protrusion being inserted into the recess.

In one example, the protrusion and the recess are in a one-to-one correspondence, and the protrusion is inserted into a corresponding recess

In one example, a surface of the first support portion facing towards the second support portion and a surface of the second support portion facing towards the first support portion are fixedly connected with each other through one to three engagement structures of the protrusion and the recess.

In one example, the display panel includes a liquid crystal display panel or an organic light emitting diode display panel.

In one example, in the organic light emitting diode display panel, the first substrate is a packaging cover plate, the second substrate is an evaporation substrate, a surface of the first support portion facing away from the second support portion is connected with the packaging cover plate, and a surface of the second support portion facing away from the first support portion is connected with the evaporation substrate.

According to another aspect of the present disclosure, there is provided a display device comprising a display panel, the display panel including the display panel as described above.

According to a further aspect of the present disclosure, there is provided a method of manufacturing the above display panel, the method comprising:

forming a plurality of first support portions, which are arranged to be spaced apart from each other, on the first substrate;

forming a plurality of second support portions, which are arranged to be spaced apart from each other, at positions on the second substrate corresponding to the first support portions;

assembling the first substrate and the second substrate into a cell such that the plurality of first support portions are respectively connected with corresponding second support portions to form spacers,

wherein the modulus of elasticity of a material of the first support portion is less than the modulus of elasticity of a material of the second support portion.

In one example, the forming the plurality of first support portions, which are arranged to be spaced apart from each other, on the first substrate comprises:

coating a first hardness material layer over the first substrate; and

performing exposure and development processes on the first hardness material layer to form the plurality of first support portions arranged to be spaced apart from each other.

In one example, the forming the plurality of second support portions, which are arranged to be spaced apart from each other, at positions on the second substrate corresponding to the first support portions comprises:

coating a second hardness material layer over the second substrate; and

performing exposure and development processes on the second hardness material layer to form the plurality of second support portions arranged to be spaced apart from each other.

In one example, the method further comprises:

forming at least one protrusion on one of a surface of the first support portion facing towards the second support portion and a surface of the second support portion facing towards the first support portion, and

forming at least one recess in the other of the surface of the first support portion facing towards the second support portion and the surface of the second support portion facing towards the first support portion, such that the first support portion and second support portion are connected with each other through an engagement structure of the protrusion and the recess.

In one example, the protrusion and the recess are in a one-to-one correspondence, and the protrusion is inserted into a corresponding recess after the first substrate and the second substrate are assembled into a cell.

In one example, at least one of the first hardness material layer and the second hardness material includes positive photoresist or negative photoresist.

In one example, in the exposure of the first hardness material layer, a first halftone mask is used for the exposure of the first hardness material layer, and the first halftone mask comprises a first transparent region, a first semitransparent region and a first light shielding region, wherein the first hardness material layer includes positive photoresist, the first transparent region corresponds to a region of the first hardness material layer for forming portions except the first support portion, the first semitransparent region corresponds to a region of the first hardness material layer for forming portions of the first support portion except the protrusion, and the first light shielding region corresponds to a region of the first hardness material layer for forming the protrusion of the first support portion.

In one example, in the exposure of the second hardness material layer, a second halftone mask is used for the exposure of the second hardness material layer, and the first halftone mask comprises a second transparent region, a second semitransparent region and a second light shielding region,

wherein the second hardness material layer includes positive photoresist, the second light shielding region corresponds to a region of the second hardness material layer for forming the second support portion, the second semitransparent region corresponds to a region of the second hardness material layer for forming the recess of the second support portion, and the second transparent region corresponds to a region of the second hardness material layer for forming other portions except the second support portion.

### BRIEF DESCRIPTION OF THE DRAWINGS

The drawings are used to provide further understanding of the present disclosure and constitute parts of the description for illustrating the present disclosure together with the following exemplary embodiments, but are not intended to limit the present disclosure. In the drawings:

FIG. 1 is a structural schematic diagram of a display panel according to an embodiment of the present disclosure;

FIG. 2 is a structural schematic diagram of a display panel according to another embodiment of the present disclosure, where a first support portion is not connected with a second support portion;

FIG. 3 is a structural schematic diagram of the display panel shown in FIG. 2, where the first support portion is connected with the second support portion;

FIG. 4 is a structural schematic diagram of a display panel according to a further embodiment of the present disclosure;

FIG. 5 is a flow chart of a method of manufacturing a display panel according to an embodiment of the present disclosure;

FIGS. 6A and 6B are respectively a method flow chart and a step flow chart of forming a first support portion on a first substrate according to an embodiment of the present disclosure; and

FIGS. 7A and 7B are respectively a method flow chart and a step flow chart of forming a second support portion on a second substrate according to an embodiment of the present disclosure.

### DETAILED DESCRIPTION

Exemplary embodiments of the present disclosure will be described hereinafter in detail with reference to the drawings. It will be understood that the exemplary embodiments described herein are only used to illustrate and explain the present disclosure, rather than limiting the present disclosure.

An existing spacer, however, has a limited compression resistance, thus an impression will be easily generated on a surface of the display panel and thereby affect visual display effect. In addition, in the organic light emitting diode display panel, spacers on either side of the sealant have insufficient supporting capacity, which will result in irregular occurrence of Newton ring on the surface of the panel thereby affecting display effect. Further, in the organic light emitting diode display panel, a cathode material (mainly, magnesium and silver) is generally evaporated by using a common mask, which will result in that the cathode material will be adhered onto a surface of the spacer; when the spacer contacts a packaging cover plate, the cathode material on the spacer will be adhered onto a surface of the packaging cover plate, so the impression phenomenon will occur on the display panel and will become serious due to a lower light transmittance of the cathode material, affecting display effect.

Thus, an inventor or inventors of the present disclosure has/have recognized the impression phenomenon of the display panel needs to be mitigated or relieved at least partly.

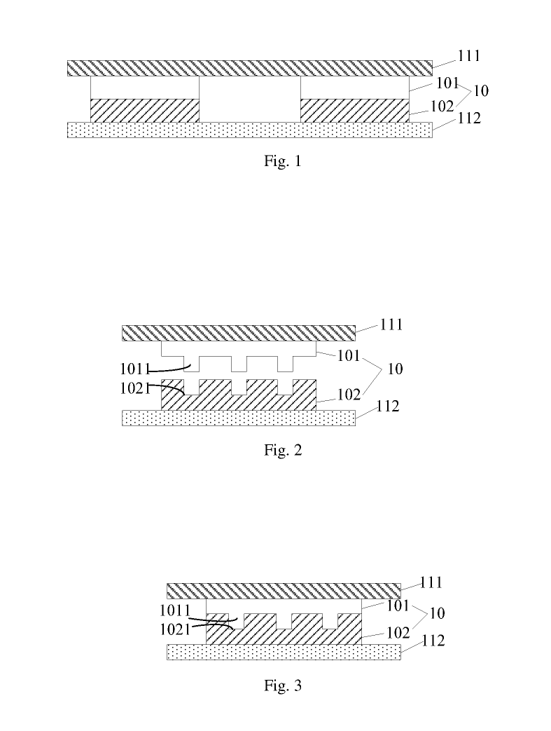

According to an embodiment of the present disclosure, there is provided a display panel, as shown in FIG. 1, comprising a first substrate 111 and a second substrate 112 arranged opposite to each other, and at least one (for example, a plurality of) spacer 10 arranged between the first substrate 111 and the second substrate 112 and spaced apart from each other, wherein the at least one spacer 10 comprises a first support portion 101 provided on the first substrate 111, and a second support portion 102 provided on the second substrate 112, the first support portion 101 and the second support portion 102 are fixedly connected with each other, and the modulus of elasticity of a material of the first support portion 101 is less than the modulus of elasticity of a material of the second support portion 102.

In the display panel provided according to the embodiment of the present disclosure, the spacer is provided into a structure including two portions and the two portions have different hardness, the first support portion having a smaller modulus of elasticity will have a better elasticity, thus when display panel is subject to an external force, the first support portion will be elastically deformed to effectively buffer the external force, thereby the impression phenomenon generated on a display surface of the display panel will be mitigated. Meanwhile, the second support portion having a larger modulus of elasticity will have a larger rigidity and provide a stronger support effect, thus the spacer formed by connecting the first support portion and the second support portion having different moduli of elasticity can not only mitigate the impression phenomenon of the display panel but also provide a better support effect to the first substrate and the second substrate of the display panel, thereby solving the above problem that the existing spacer has a poor supporting capacity due to reasons such as poor compression resistance and the like and the impression easily occurs on the display panel.

Specifically, a spacer is often provided in the display panel for providing a supporting effect, while the spacer of the display panel in the present disclosure has a structure including two portions, the first support portion 101 and the second support portion 102 as shown in FIG. 1, wherein the first support portion 101 is provided on the first (display) substrate 111, the second support portion 102 is provided on the second (display) substrate 112, the first support portion 101 and the second support portion 102 are fixedly connected with each other when assembling the first substrate 111 and the second substrate 112 into a cell, such that the first support portion 101 and the second support portion 102 are combined to form the spacer 10. Further, the modulus of elasticity of a material of the first support portion 101 is different from the modulus of elasticity of a material of the second support portion 102, for example, the modulus of elasticity of the material of the first support portion 101 is less than the modulus of elasticity of the material of the second support portion 102. It will be appreciated that, a material having a smaller modulus of elasticity will have a better elasticity and will be elastically deformed when being subject to an external force so as to buffer the external force, such that an impression will not easily occur on the display surface of the display panel, while a material having a larger modulus of elasticity will have a larger rigidity so as to enable a better support effect, thus the spacer formed by combining two materials having different moduli of elasticity can not only provide a support effect but also mitigate the impression phenomenon, solving the above problem of occurrence of impression on the display panel due to lower compression resistance and the like of the existing spacer.

It will be understood that in order to arrange a plurality of spacers 10 between the first substrate 111 and the second substrate 112, a plurality of the first support portions 101 are formed on the first substrate 111 and correspondingly, a plurality of the second support portions 102 are formed on the second substrate 112.

It is noted that it means the larger the modulus of elasticity of a material is, the larger the elastic deformation resistance and the hardness of the material are; whereas the smaller the modulus of elasticity of a material is, the smaller the elastic deformation resistance of the material is and the smaller the hardness of the material is.

Generally, an organic polymer material, for example, a polyimide composite resin, is selected as materials of the first support portion 101 and the second support portion 102; considering that the larger the degree of polymerization of a material is, the larger the hardness of the material is, thus a polyimide composite resin having a smaller degree of polymerization may be selected as the material of the first support portion 101 having a smaller modulus of elasticity, and another polyimide composite resin having a larger degree of polymerization may be selected as the material of the second support portion 102 having a larger modulus of elasticity.

It will be appreciated that when the first substrate 111 and the second substrate 112 are assembled into a cell, the first support portion 101 and the second support portion 102 may be fixedly connected with each other through an adhesive in order to form the spacer 10. Of course, the first support portion 101 and the second support portion 102 may also be fixedly connected with each other in other suitable ways, for example, inserting connection, snap fit or the like.

In an example, as shown in FIG. 2, in order that the spacer 10 can provide a better support effect and decrease use of adhesive between the first support portion 101 and the second support portion 102, at least one protrusion 1011 is formed on a surface of the first support portion 101 facing towards the second support portion 102, at least one recess 1021 is formed in a surface of the second support portion 102 facing towards the first support portion 101, the protrusion 1011 and the recess 1021 are in a one-to-one correspondence, and the protrusion 1011 is inserted into a corresponding recess 1021.

Specifically, the surface of the first support portion 101 facing towards the second support portion 102 is provided with the protrusion 1011, which can just be inserted into the recess 1021 provided in the surface of the second support portion 102. As shown in FIG. 3, it shows a structural schematic diagram where the protrusion 1011 is inserted into the recess 1021. As such, connection is achieved through engagement structures including the recess and the protrusion on two surfaces of the first support portion 101 and the second support portion 102 facing each other, improving the anti-shear ability of the display panel, such that the first support portion 101 and the second support portion 102 can be stably connected with each other, thus, the spacer 10 formed by combining the first support portion 101 and the second support portion 102 can provide a more stable support effect.

It is noted that the number of the protrusion 1011 of the first support portion 101 and the number of the recess 1021 of the second support portion 102 are desired to be in a one-to-one correspondence, but the numbers of the protrusion 1011 and the recess 1021 may also be different from each other and will not be particularly limited, and may be selected by those skilled in the art as required.

In one example, as shown in FIG. 3, one to three protrusions 1011 are formed on the surface of the first support portion 101 facing towards the second support portion 102, and one to three recesses 1021 are formed in the surface of the second support portion 102 facing towards the first support portion 101.

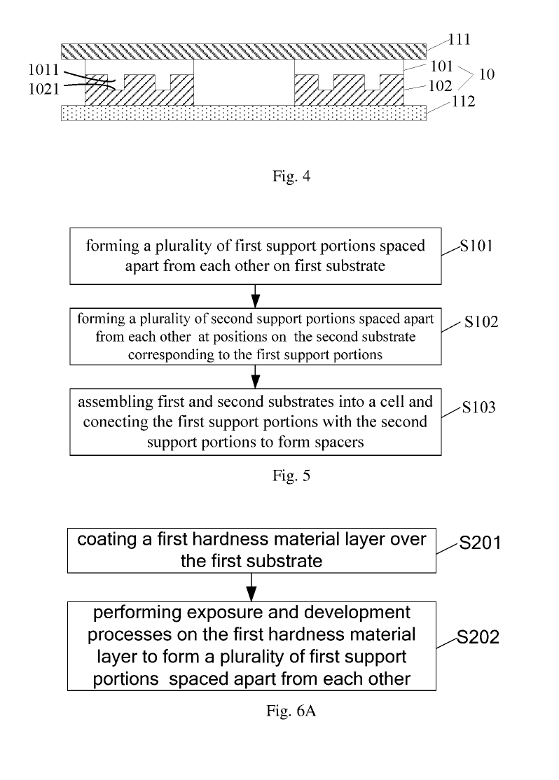

It will be appreciated that, the number of the protrusion 1011 on the first support portion 101 and the number of the recess 1021 on the second support portion 102 may be set according to sizes of the first support portion 101 and the second support portion 102. In the spacer 10 shown in FIG. 4, the first support portion 101 is provided with two protrusions 1011, and correspondingly the second support portion 102 is provided with two recesses 1021, such that the first support portion 101 and the second support portion 102 can provide a more stable support effect while having allowable sizes.

Herein, it is noted that the first support portion 101 and the second support portion 102 may be connected together through engagement structures including the protrusion and the recess, which are not limited to specific forms shown in FIGS. 2-4, for example, it may be possible that the first support portion 101 is provided with a recess and correspondingly the second support portion 102 is provided with a protrusion. In the present disclosure, the forms shown in FIGS. 2-4 are only used as examples for purpose of illumination, but are not intended to limit specific contents of the present disclosure.

It will be understood that, the display panel may be a liquid crystal display panel, or may be an organic light emitting diode display panel. In one example, the display panel includes an organic light emitting diode display panel.

Specifically, when the display panel is an organic light emitting diode display panel, taking the first substrate 111 is a packaging cover plate and the second substrate 112 is an evaporation substrate as an example for illustration, a surface of the first support portion 101 facing away from the second support portion 102 is connected with the packaging cover plate 111, and a surface of the second support portion 102 facing away from the first support portion 101 is connected with the evaporation substrate 112.

It is noted that the first substrate 111 is a packaging cover plate, which will be easily subject to an external force, and the first support portion 101 having a smaller modulus of elasticity has a good elasticity characteristic and is provided on a side of the packaging cover plate, such that when an upper surface of the first substrate 111 will be elastically deformed when receiving a pressure; the evaporation substrate is generally located at a lower position, which requires the second support portion 102 provided on the evaporation substrate to provide a better support effect, thus the second support portion 102 having a larger modulus of elasticity is provided on a side of the evaporation substrate. This combined spacer 10, when used in the display panel, can not only buffer impression but also provide a better support effect.

It will be appreciated that in embodiments of the present disclosure, whether the first substrate 111 or the second substrate 112 is used as an evaporation substrate or a packaging cover plate is not particularly limited. In practice, if the first substrate 111 is an evaporation substrate and the second substrate 112 is a packaging cover plate, then a surface of the first support portion 101 facing away from the second support portion 102 is connected with the evaporation substrate, and a surface of the second support portion 102 facing away from the first support portion 101 is connected with the packaging cover plate. In order to avoid elastical deformation of the upper surface of the evaporation substrate due to pressure when the evaporation substrate is jointed to the packaging cover plate in an up to down direction, it is required that the second support portion 102 provided on the packaging cover plate has a good rigidity for providing a stable support.

In the display panel provided according to the present disclosure, the spacer of the display panel is formed into a configuration where the first support portion and second support portion are combined, and materials of the two portions have different hardness, such that the spacer can not only provide better support effect, but also mitigate, when a side of the display panel is applied with a force, the force applied to the display panel and reduce impression caused to the applied force. Further, surfaces of the first support portion and the second support portion which face each other are provided with protrusion-recess engagement structures, such that anti-shear ability between the first support portion and the second support portion can be enhanced, and stability in connection between the first support portion and the second support portion is improved, thereby support stability of the spacer is improved, and the phenomenon where Newton ring occurs due to weaker supporting capacity of the existing spacers at an edge of the display panel can be effectively reduced.

According to another embodiment of the present disclosure, there is provided a display device comprising a display panel, the display panel may be the display panel as described above.

Specifically, the display device may be a product having a display function, such as a mobile phone, a tablet computer, a television, a display, a notebook computer or the like.

The display device of the present disclosure comprises the display panel described above, thus when the display device is subject to an external force, no impression will be easily generated, improving the display effect of the display device.

In the display panel and the display device provided according to the present disclosure, the spacer is provided in a configuration including two portions, and the two portions have different hardness; the first support portion having a smaller modulus of elasticity will have a better elasticity, thus when the display panel is subject to an external force, the first support portion will be elastically deformed to effectively buffer the external force, thereby the impression phenomenon generated on a display surface of the display panel will be mitigated. Meanwhile, the second support portion having a larger modulus of elasticity will have a larger rigidity and provide a stronger support effect, thus the spacer formed by connecting the first support portion and the second support portion having different moduli of elasticity can not only mitigate the impression phenomenon of the display panel but also provide a better support effect to the first substrate and the second substrate of the display panel, solving the above problem that the existing spacer has a poor supporting capacity due to reasons such as lower compression resistance and the like and the impression easily occurs on the display panel. The display device provided according to the present disclosure comprises the display panel described above, thus when the display device is subject to an external force, no impression will be easily generated, improving the display effect of the display device.

According to a further embodiment of the present disclosure, there is provided a method of manufacturing a display panel. With reference to the flow chart of the method of manufacturing a display panel shown in FIG. 5, the method comprises:

S101: forming a plurality of first support portions 101, which are arranged to be spaced apart from each other, on a first substrate 111;

Specifically, the plurality of first support portions 101 are formed on the first substrate 111 of the display panel, and every two adjacent first support portions 101 are spaced apart from each other.

S102: forming a plurality of second support portions 102, which are arranged to be spaced apart from each other, at positions on a second substrate 112 corresponding to the first support portions 101;

Specifically, similar to the way of forming the first support portions 101, the second support portions 102 are formed at positions on the second substrate 112 corresponding to the first support portions 101.

S103: assembling the first substrate 111 and the second substrate 112 into a cell such that the plurality of first support portions 101 are respectively connected with corresponding second support portions 102 to form spacers 10,

wherein the modulus of elasticity of a material of the first support portion 101 is less than the modulus of elasticity of a material of the second support portion 102.

Specifically, when assembling the first substrate 111 and the second substrate 112 into a cell, surfaces of the first support portion 101 and the second support portion 102 which face each other are connected together, such that the first support portion 101 and the second support portion 102 are connected together to form the spacers 10, which can provide a support effect between the first substrate 111 and the second substrate 112.

It is noted that a sequence of the step of forming the first support portion 101 on the first substrate 111 and the step of forming the second support portion 102 on the second substrate 112 is not limited; it may be possible to firstly form the first support portions 101 formed on the first substrate 111 and then form the second support portions 102 on the second substrate 112, or it may be also possible to firstly form the second support portions 102 on the second substrate 112 and then form the first support portions 101 on the first substrate 111, or it may be also possible to form the first support portions 101 on the first substrate 111 and to form the second support portions 102 on the second substrate 112 simultaneously.

In the method of manufacturing a display panel provided according to the present disclosure, the first support portions 101 are formed on the first substrate 111 of display panel, the second support portions 102 are formed on the second substrate 112, and then the first support portions 101 on the first substrate 111 and corresponding second support portions 102 on the second substrate 112 are connected together to form the spacers 10 providing support between the two substrates. In the display panel manufacturing by this method, the spacer is provided in a configuration including two portions, and the two portions have different modulus of elasticity, where the first support portion 101 having a smaller modulus of elasticity has a characteristic of better elasticity, the second support portion 102 having a larger modulus of elasticity has a characteristic of a larger hardness and providing a stable support, and the spacer formed by combining the two portions, when used in the display panel, can provides that the impression will not be easily generated on the display panel when the display panel is subject to an external force, and can provides a better support effect for the display panel.

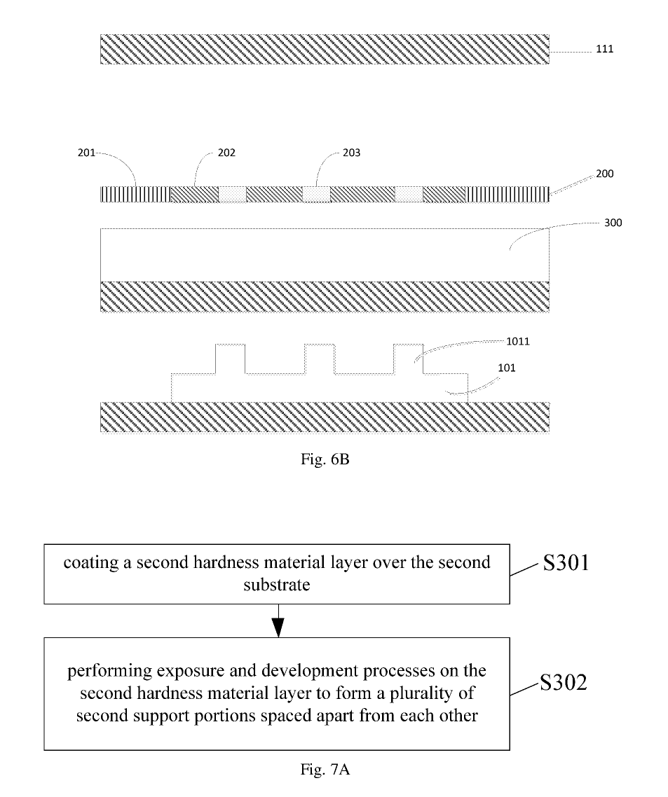

According to another embodiment of the present disclosure, as shown in FIGS. 6A and 6B, the forming a plurality of first support portions 101, which are arranged to be spaced apart from each other, on the first substrate 111 in step S101 may specifically comprise:

S1011: coating a first hardness material layer 300 over the first substrate 111; Specifically, as described above, the first hardness material layer 300 may include a polyimide composite resin material having a low degree of polymerization, which possesses characteristics such as good elasticity and strong adhesion.

S1012: performing exposure and development processes on the first hardness material layer 300 to form a plurality of first support portion 101 arranged to be spaced apart from each other;

Specifically, the first hardness material layer 300 coated on the first substrate 111 is processed through exposure and development so as to obtain the plurality of first support portion 101 arranged to be spaced apart from each other.

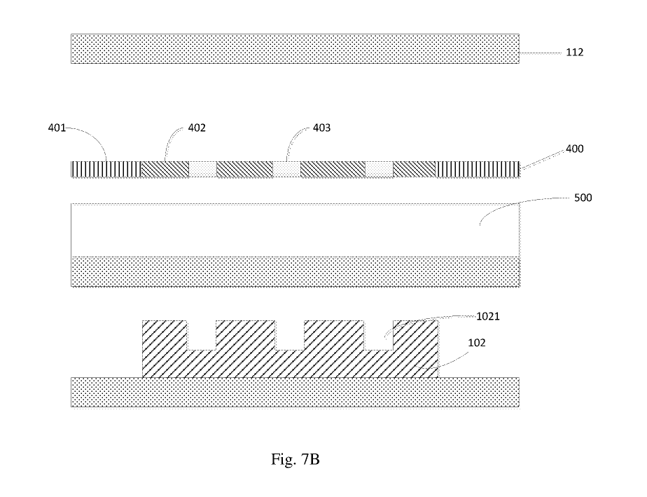

A shown in FIGS. 7A and 7B, the forming a plurality of second support portions 102, which are arranged to be spaced apart from each other, at positions on the second substrate 112 corresponding to the first support portions 101 in step S102 comprises:

S1021: coating a second hardness material layer 500 over the second substrate 112;

Specifically, as described above, the second hardness material layer 500 may include a polyimide composite resin material having a high degree of polymerization, which possesses characteristics such as good rigidity and strong adhesion.

S1022: performing exposure and development processes on the second hardness material layer 500 to form the plurality of second support portions 102 arranged to be spaced apart from each other;

Specifically, similar to forming the first support portions 101, the second hardness material layer 500 is processed through exposure and development so as to obtain the second support portions 102.

It will be appreciated that, the polyimide composite resin material having a low degree of polymerization and another polyimide composite resin material having a high degree of polymerization are each obtained by compounding a polyimide based material with other compounds, and the degrees of their polymerizations are adjusted so that polyimide composite resin materials having different hardness can be obtained.

In one example, a surface of the first support portion 101 facing towards the second support portion 102 is formed with at least one protrusion 1011, a surface of the second support portion 102 facing the first support portion 101 is formed with at least one recess 1021, the protrusion 1011 and the recess 1021 are in a one-to-one correspondence, and the protrusion 1011 is inserted into a corresponding recess 1021 after the first substrate 111 and the second substrate 112 are assembled into a cell.

Specifically, a surface of the first support portion 101 continues to be processed through exposure and development so as to form protrusions 1011 on a surface of the first support portion 101 facing away from the first substrate 111, and the number of the protrusions 1011 may be set according to specific size of the first support portion 101 and will not be limited herein.

Accordingly, corresponding to forming of the protrusion 1011, a surface of the second support portion 102 continues to be processed through exposure and development so as to form recesses 1021 in a surface of the second support portion 102 facing away from the second substrate 112, the number of the recesses 1021 and the number of the protrusions 1011 are equal to each other, for example in a one-to-one correspondence, and positions of the recesses 1021 correspond to positions of the protrusions 1011.

It will also be understood that since the protrusion 1011 can be inserted into the recess 1021, the depth of the recess 1021 needs to be not less than the protruding height of the protrusion 1011. Exemplarily, in order to achieve a stable connection between the first support portion 101 and the second support portion 102, the depth of the recess 1021 is equal to the protruding height of the protrusion 1011, and the width of the recess 1021 also matches with the width of the protrusion 1011, such that the recess 1021 can just receive the protrusion 1011 therein.

After forming the protrusion 1011 and the recess 1021, assembling the first substrate 111 and the second substrate 112 into the shell further comprises inserting the protrusion 1011 into the recess 1021 such that the first support portion 101 and the second support portion 102 are connected with each other to form the spacer 10.

It will be appreciated that sequence of forming of the protrusion 1011 and the recess 1021 is also not limited, the protrusion 1011 may be firstly formed, or the recess 1021 may be firstly formed, or the protrusion 1011 and the recess 1021 may be formed at the same time.

Referring to FIG. 6B, in the exposure step of the first hardness material layer, a first halftone mask 200 is used for the exposure of the first hardness material layer 300, and the first halftone mask 200 comprises a first transparent region 201, a first semitransparent region 202 and a first light shielding region 203. In an example, the first hardness material layer 300 includes positive photoresist, the first transparent region 201 corresponds to a region of the first hardness material layer 300 for forming portions except the first support portion 101, the first semitransparent region 202 corresponds to a region of the first hardness material layer 300 for forming portions of the first support portion 101 except the protrusion 1011, and the first light shielding region 203 corresponds to a region of the first hardness material layer 300 for forming the protrusion 1011 of the first support portion 101. Referring to FIG. 7B, in the exposure step of the second hardness material layer 500, a second halftone mask 400 is used for the exposure of the second hardness material layer 500, and the second halftone mask 400 comprises a second transparent region 401, a second semitransparent region 403 and a second light shielding region 402. In an example, the second hardness material layer 500 includes positive photoresist, the second light shielding region 401 corresponds to a region of the second hardness material layer 500 for forming the second support portion 102, the second semitransparent region 403 corresponds to a region of the second hardness material layer 500 for forming the recess 1021 of the second support portion 102, and the second transparent region 402 corresponds to a region of the second hardness material layer 500 for forming other portions of the second support portion 102 except the recess 1021.

Specifically, a first hardness material layer, for example, a layer of positive photoresist, is coated on the first substrate 111, and then is processed through two exposure operations by using a halftone mask so as to obtain a plurality of first support portions 101 formed with protrusions 1011; also, a second hardness material layer, for example, a layer of positive photoresist, is coated on the second substrate 112, and then is processed through two exposure operations by using a halftone mask so as to obtain a plurality of second support portions 102 formed with recesses 1021. However, it may be provided by those skilled in the art according to existing knowledge that at least one of the first hardness material layer and the second hardness material layer includes negative photoresist, which will not be described in detail herein.

In the method of manufacturing an display panel according to the present disclosure, the first support portions 101 are formed on the first substrate 111 of display panel, the second support portions 102 are formed on the second substrate 112, the modulus of elasticity of a material of the first support portion 101 formed on the first substrate 111 is different from the modulus of elasticity of a material of the second support portion 102 formed on the second substrate 112, the first support portion 101 having a smaller modulus of elasticity has a characteristic of better elasticity and thus can buffer an external force applied to the display panel, while the second support portion 102 having a larger modulus of elasticity has a characteristic of better rigidity and thus can provide a better support effect; the first support portions 101 on the first substrate 111 and corresponding second support portions 102 on the second substrate 112 are connected together to form the spacers 10, solving the problem that the impression will be easily generated on the prior art display panel when the display panel is subject to an external force because the existing spacer has a poor supporting capacity due to reasons such as lower compression resistance and the like. Further, the protrusions 1011 and the recesses 1021 are respectively formed on surfaces of the first support portion 101 and the second support portion 102 facing each other, thus the anti-shear ability is enhanced between the first support portion 101 and the second support portion 102, such that the connection between two support portions 101, 102 becomes more stable, thereby the spacers 10 formed by connecting the first support portion 101 and the second support portion 102 can provide a better support effect.

It will be appreciated that the above embodiments are merely exemplary embodiments for the purpose of explaining the principle of the present disclosure, however, the present disclosure is not limited thereto. It will be apparent to those skilled in the art that various changes and modifications can be made thereto without departing from the spirit and principle of the present disclosure, and such changes and modifications also fall within the scope of the present disclosure.

What is claimed is:

1. A display panel, comprising:
a first substrate;
a second substrate arranged to face the first substrate; and
at least one spacer arranged between the first substrate and the second substrate and spaced apart from each other, wherein the at least one spacer comprises:
a first support portion provided on the first substrate, and
a second support portion provided on the second substrate, wherein the first support portion and the second support portion are fixedly connected with each other, and a modulus of elasticity of a material of the first support portion is less than a modulus of elasticity of a material of the second support portion.

2. The display panel according to claim 1, wherein the first support portion and/or second support portion are/is made of an organic polymer material.

3. The display panel according to claim 2, wherein the organic polymer material includes polyimide composite resin.

4. The display panel according to claim 3, wherein:
the first support portion and second support portion are both made of the organic polymer material that includes polyimide composite resin, and
a degree of polymerization of the polyimide composite resin of the first support portion is less than a degree of polymerization of the polyimide composite resin of the second support portion.

5. The display panel according to claim 1, wherein the first support portion and second support portion are fixedly connected with each other by an adhesive.

6. The display panel according to claim 1, wherein the first support portion and second support portion are connected with each other through an engagement structure including a protrusion and a recess.

7. The display panel according to claim 6, wherein one of a surface of the first support portion facing towards the second support portion and a surface of the second support portion facing towards the first support portion is formed with at least one protrusion, and the other one is formed with at least one recess, the at least one protrusion being inserted into the at least one recess.

8. The display panel according to claim 7, wherein the at least one protrusion and the at least one recess are in one-to-one correspondence, and each protrusion is inserted into a corresponding recess.

9. The display panel according to claim 6, wherein a surface of the first support portion facing towards the second support portion and a surface of the second support portion facing towards the first support portion are fixedly connected with each other through one to three engagement structures of the protrusion and the recess.

10. The display panel according to claim 1, wherein the display panel comprises a liquid crystal display panel or an organic light emitting diode display panel.

11. The display panel according to claim 10, wherein the display panel comprises an organic light emitting diode display panel, and:
the first substrate is a packaging cover plate,
the second substrate is an evaporation substrate,
a surface of the first support portion facing away from the second support portion is connected with the packaging cover plate, and
a surface of the second support portion facing away from the first support portion is connected with the evaporation substrate.

12. A display device comprising a display panel, the display panel including the display panel of claim 1.

13. A method of manufacturing the display panel of claim 1, the method comprising:
forming a plurality of first support portions, which are arranged to be spaced apart from each other, on the first substrate;
forming a plurality of second support portions, which are arranged to be spaced apart from each other, at positions on the second substrate corresponding to the first support portions; and
assembling the first substrate and the second substrate into a cell such that the plurality of first support portions are respectively connected with corresponding second support portions to form spacers,
wherein the modulus of elasticity of the material of the first support portion is less than the modulus of elasticity of the material of the second support portion.

14. The method according to claim 13, wherein forming the plurality of first support portions, which are arranged to be spaced apart from each other, on the first substrate comprises:
coating a first hardness material layer over the first substrate; and
performing exposure and development processes on the first hardness material layer to form the plurality of first support portions arranged to be spaced apart from each other.

15. The method according to claim 14, wherein forming the plurality of second support portions, which are arranged to be spaced apart from each other, at positions on the second substrate corresponding to the first support portions comprises:
coating a second hardness material layer over the second substrate; and
performing exposure and development processes on the second hardness material layer to form the plurality of second support portions arranged to be spaced apart from each other.

16. The method according to claim 13, further comprising:
forming at least one protrusion on one of a surface of the first support portion facing towards the second support portion and a surface of the second support portion facing towards the first support portion, and
forming at least one recess in the other of the surface of the first support portion facing towards the second support portion and the surface of the second support portion facing towards the first support portion, such that the first support portion and second support portion are connected with each other through an engagement structure of the protrusion and the recess.

17. The method according to claim 16, wherein the at least one protrusion and the at least one recess are in one-to-one correspondence, and each protrusion is inserted into a corresponding recess after the first substrate and the second substrate are assembled into a cell.

18. The method according to claim 15, wherein at least one of the first hardness material layer and the second hardness material includes positive photoresist or negative photoresist.

19. The method according to claim 18, wherein in the exposure of the first hardness material layer, a first halftone mask is used for the exposure of the first hardness material layer, and the first halftone mask comprises a first transparent region, a first semitransparent region and a first light shielding region,
wherein the first hardness material layer includes positive photoresist, the first transparent region corresponds to a region of the first hardness material layer for forming portions except the first support portion, the first semitransparent region corresponds to a region of the first hardness material layer for forming portions of the first support portion except the protrusion, and the first light shielding region corresponds to a region of the first hardness material layer for forming the protrusion of the first support portion.

20. The method according to claim 18, wherein in the exposure of the second hardness material layer, a second halftone mask is used for the exposure of the second hardness material layer, and the first halftone mask comprises a second transparent region, a second semitransparent region and a second light shielding region,
wherein the second hardness material layer includes positive photoresist, the second light shielding region corresponds to a region of the second hardness material layer for forming the second support portion, the second semitransparent region corresponds to a region of the second hardness material layer for forming the recess of the second support portion, and the second transparent region corresponds to a region of the second hardness material layer for forming other portions except the second support portion.
